(19) United States
(12) Patent Application Publication
(10) Pub. No.: US 2026/0163326 A1
(43) Pub. Date: Jun. 11, 2026

(54) REFLECTOR FOR USE IN LASER ARCHITECTURE

(71) Applicants: COMPOUNDTEK PTE. LTD., Singapore (SG); NANYANG TECHNOLOGICAL UNIVERSITY, Singapore (SG)

(72) Inventors: Jia Xu BRIAN SIA, Singapore (SG); Hong WANG, Singapore (SG); Kian Siong ANG, Singapore (SG)

(21) Appl. No.: 18/722,102

(22) PCT Filed: Feb. 14, 2023
(86) PCT No.: PCT/SG2023/050078

§ 371 Date: Jun. 20, 2024

(51) Int. Cl. H01S 3/08; H01S 5/14; H01S 5/30

(52) U.S. Cl. CPC H01S 3/08059; H01S 5/14; H01S 5/3013; H01S 5/3031

(57) ABSTRACT

The present invention relates to a reflector (300) for laser architecture. The reflector (300) includes a coupling section (310) formed of waveguides and including three ports (302-306) and a loop section (310) formed of a waveguide and optically coupled to the coupling section (310). The reflector (300) is an ultra-broadband on-chip laser coupling section reflector or an ultra-broadband coupling section laser reflector and is operable in an O band, C band or L band.

### FIELD OF THE INVENTION

The disclosures made herein relate generally to laser devices, and more particularly to a reflector for use in a laser architecture.

### BACKGROUND OF THE INVENTION

In general, Silicon (Si) photonics is an integrated optical platform that enables the integration of multiple photonic components (e.g., multiplexer, modulator, photodetector or the like) to be implemented on a silicon-on-insulator chip. By leveraging on advanced silicon manufacturing techniques, these photonic circuits can be manufactured in a scalable and low-cost fashion. However, the silicon material is an inefficient emitter of light. As such, it has not been possible to realize a monolithic Si laser that can be electrically-pumped and operate at room temperature with good performance. The development of hybrid III-V/Si hybrid/heterogeneous lasers in recent years has disparaged this withstanding problem in silicon photonics. In such laser architectures, the III-V provides optical gain, whereas silicon photonics functions as a passive silicon laser cavity, providing functionalities such as wavelength selective feedback. Due advanced silicon manufacturing techniques, the passive silicon laser cavity can enable optical functionalities with high quality, thereby leading to superior performance in hybrid/heterogeneous III-V/Si lasers as compared to their III-V counterpart.

Wavelength tunable lasers will serve as an integral component in current and upcoming optical systems. By replacing an array of single-wavelength distributed feedback (DFB) lasers with a tunable laser, reduction in issues such as system complexity, wavelength contention in optical communications and inventory costs can be achieved. While not exhaustive, other applications of wavelength tunable lasers include the identification of gas species via specific wavelength absorption features, as well as enabling the differential absorption Light Detection and Ranging (LIDAR) technique.

In general, the passive silicon laser cavity in hybrid/heterogeneous III-V/Si lasers consists of devices that enables several key functionalities: optical emission and gain, wavelength selectivity to enable the laser to lase via mode competition, reflector. These optical functionalities (100) can be arranged in the following forms ((i.e., first mirror (102a), a gain medium (104), a wavelength filter (106) and a second mirror (102b)) illustrated in FIG. 1 in the laser. The wavelength selectivity can be enabled via dual or triple microring/racetrack wavelength filters. Typically, silicon reflectors are implemented via a Sagnac loop reflector (200b) or a 1×2 MMI (multi-mode interferometer)-based reflector (200a) as illustrated in FIG. 2B and FIG. 2A. The three most widely used optical bands are O (1260-1360 nm), C (1535-1565 nm) and L (1565-1625 nm). As such, it will be pertinent to implement the abovementioned optical functionalities in such a manner that it does not degrade across the desired operating wavelength for the wavelength-tunable lasers. Of the abovementioned optical functionalities illustrated in FIG. 2A and FIG. 2B, the silicon reflector, as currently implemented via a Sagnac loop or 1×2 MMI reflector respectively is sensitive to wavelength changes. Changes in optical wavelength will lead to changes in the reflectivity of Sagnac loop, increase in the insertion loss of 1×2 MMI-based reflector (200a). These changes will adversely affect laser performance.

In the conventional methods and systems, an optoelectronic circuit including an IC chip made up of a substrate in which an optical waveguide and a mirror have been fabricated, the substrate having a first lens formed thereon. The mirror is aligned with the optical waveguide and the first lens is aligned with the mirror to form an optical path connecting the first lens, the mirror, and the optical waveguide. An optical coupler includes a second lens, the optical coupler affixed to the substrate and positioned to align the second lens with the first lens so as to couple an optical signal into or out of the optical waveguide within the IC chip.

### SUMMARY OF THE INVENTION

The present invention relates to a reflector for use in a laser architecture. The reflector comprises a coupling section formed of waveguides and including a first port, a second port and a third port. The reflector further comprises a loop section formed of at least one waveguide and optically coupled to the coupling section. The coupling section is configured as a trident, such that a first coupling gap is formed between the first port and the second port and a second coupling gap is formed between the first port and the third port. The first coupling gap and the second coupling gap are symmetric.

The first port is configured to split a light wave exiting the first port and symmetrically input the split light waves into the second port and the third port, such that each split light wave entering through one of the second port and the third port travels along the loop section, exits through the other of the second port and the third port and recombines with the other split light wave at the first port.

In one aspect, a first surface of the first port is parallel to a first surface of the second port and a second surface of the first port is parallel to a first surface of the third port.

Preferably, the laser architecture is a laser cavity that is a part of a hybrid III-V/silicon laser device or a heterogeneous III-V/silicon laser. The reflector is at least one of an ultra-broadband on-chip laser coupling section reflector and an ultra-broadband coupling section laser reflector. More preferably, the reflector is operable in at least one of an O band, C band and L band.

In one embodiment, a reflector for use in a laser architecture comprises a first coupling section, a second coupling section and at least one loop section. Each of the first coupling section and the second coupling section is formed of waveguides and includes a first port, a second port and a third port. The loop section is formed of a waveguide and is optically coupled to the second coupling section.

In the first coupling section, the first port and the second port form a first spaced coupling gap and the first port and the third port form a second spaced coupling gap, wherein the first spaced coupling gap and the second spaced coupling gap are asymmetrical. In the second coupling section, the first port and the second port form a first spaced coupling gap and the first port and the third port form a second spaced coupling gap, wherein the first spaced coupling gap and the second spaced coupling gap are symmetrical. Furthermore, the first port of the second coupling section is optically coupled to the third port of the first coupling section.

In an embodiment, the coupling section enables wavelength independent operation in the reflector.

In an embodiment, the coupling section enables broadband low insertion loss levels in the reflector.

In an embodiment, the reflector is not phase dependent, so that the reflector is implemented on a photonic platform with a high thermo-optic effect, wherein an operation of the reflector is not dependent on changes in effective optical path length due to drifts in environmental temperatures.

In an embodiment, the reflector is capable of temperature independent operation.

In an embodiment, the reflector operates based on an adiabatic mode evolution.

In an embodiment, a reflectivity of the reflector is determined by the splitting ratio of the coupling section, wherein a fraction of power split to the second port, and the remaining to the third port.

In an embodiment, a power from the second port will exit via a straight waveguide and represent a transmittance of the reflector.

In an embodiment, the first port of the coupling section functions as a power splitter spaced equally from two ports coupled to the loop section, wherein the power splitter splits the optical signal equally into beams, and wherein each split beam is propagated through one of the two ports of the loop section and returned to the splitter port through the other of the two ports.

In an embodiment, the reflector is at least one of an ultra-broadband on-chip laser coupling section reflector and an ultra-broadband coupling section laser reflector, wherein the laser architecture is a type 1 laser architecture and a type 2 laser architecture, wherein the reflector is operated in at least one of an O band, C band and L band.

### BRIEF DESCRIPTION OF THE ACCOMPANYING DRAWINGS

The present invention will be fully understood from the detailed description given herein below and the accompanying drawings which are given by way of illustration only, and thus are not limitative of the present invention, wherein:

FIG. 1 illustrates optical functionalities of a single wavelength tunable laser, in accordance with prior art.

FIG. 2A illustrates an MMI-based reflector, in accordance with prior art.

FIG. 2B illustrates a Sagnac-loop reflector, in accordance with prior art.

FIG. 3 illustrates a schematic view of a reflector, in accordance with one embodiment of the present invention.

FIGS. 4A & 4B illustrate block diagrams of two types of hybrid III-V/Si lasers, in accordance with one embodiment of the present invention.

FIG. 5A illustrates a change in reflectance value of a partial Sagnac loop reflector from λ=1.26-1.36 μm wherein a Sagnac loop reflector is designed to have a reflectance of 50% at λ=1.31 μm.

FIG. 5B illustrates a change in insertion loss value of the MMI-based full reflector from λ=1.26-1.36 μm, wherein the MMI-based full reflector is optimized at from λ=1.31 μm.

FIG. 6A illustrates an operation bandwidth of the 50/50 splitter at λ=1.26-1.36 μm, in accordance with one embodiment of the present invention.

FIG. 6B illustrates an operation bandwidth of the reflector at λ=1.26-1.36 μm, in accordance with one embodiment of the present invention.

FIG. 6C illustrates a broadband insertion loss levels of the reflector at λ=1.26-1.36 μm, in accordance with one embodiment of the present invention.

FIG. 7 illustrates an electric field distribution of the splitter, in accordance with one embodiment of the present invention.

FIG. 8A illustrates an operation bandwidth of the 60/40, 70/30 and 80/20 splitters at λ=1.26-1.36 μm, in accordance with one embodiment of the present invention.

FIG. 8B illustrates broadband insertion loss levels of the splitters in the FIG. 9A at λ=1.26-1.36 μm, in accordance with one embodiment of the present invention.

FIG. 9 illustrate schematic view of a reflector, in accordance with another embodiment of the present invention.

FIG. 10A illustrates operation bandwidth of the 60/40 partial reflector at λ=1.26-1.36 μm, in accordance with one embodiment illustrated in FIG. 9.

FIG. 10B illustrates broadband insertion loss levels of the coupling section 60/40 reflector (λ=1.26-1.36 μm, in accordance with one embodiment illustrated in FIG. 9.

FIGS. 11A & 11B illustrate operation of the splitters not affected by operating temperature in accordance with one embodiment illustrated in FIG. 9.

### DETAILED DESCRIPTION OF THE INVENTION

Detailed description of preferred embodiments of the present invention is disclosed herein. It should be understood, however, that the embodiments are merely exemplary of the present invention, which may be embodied in various forms. Therefore, the details disclosed herein are not to be interpreted as limiting, but merely as the basis for the claims and for teaching one skilled in the art of the invention. The numerical data or ranges used in the specification are not to be construed as limiting. The following detailed description of the preferred embodiments will now be described in accordance with the attached drawings, either individually or in combination.

The present invention relates to a reflector for use in a laser architecture. The reflector includes a coupling section formed by a first port, a second port, and a third port. A first coupling gap is formed between the first port and the second port, and a second coupling gap is formed between the first port and the third port. The first coupling gap and the second coupling gap are symmetrically spaced each other, so that the coupling section is provided with symmetrically spaced coupling gaps. A light wave exiting the first port is split symmetrically and the split light waves are inputted to the second port and the third port. Each light wave enters one of the second port and the third port, travels along a loop section of the reflector, exits through the other of the second port and the third port and recombines with the other split light wave at the first port.

The present inventions is applicable for operations at bandwidths in excess of 120 nm across O, C and L bands with negligible insertion loss levels. The proposed reflector is independent of operation wavelength and temperature. The present invention can also be implemented in any integrated optical platform, across any wavelength region as long as the material absorption of the particular wavelength region is not significant.

Unlike conventional Sagnac loop reflectors and 1×2 MMI based reflectors, which are typically implemented in hybrid/heterogeneous III-V/Si lasers, the present invention enables wavelength independent operation at low insertion loss levels. The present invention allows 100% reflectance with low insertion loss when configured with a single coupling section and allows partial reflectance when two coupling sections are cascaded, wherein the reflectance level can be controlled by moving a splitter port of one of the coupling section closer to one of the other two ports of the coupling section.

The Sagnac loop reflectors and 1×2 MMI reflectors are implemented in hybrid/heterogeneous III-V/Si lasers. These reflectors are phase dependent, and their operation depends on the effective optical path length that the light wave experiences. On the SOI platform, where the thermo-optic effect of the silicon material is high, this implies that effectiveness of designed devices is well influenced by drifts in environmental temperatures. The proposed coupling section reflector in the patent disclosure operates based on the adiabatic mode evolution, indicating temperature resiliency. Unlike Sagnac loop reflectors and 1×2 MMI reflectors, the present invention is capable of temperature independent operation.

Referring now to the drawings and more particularly to FIG. 3 through FIG. 11B, where similar reference characters denote corresponding features consistently throughout the figures, there are shown preferred embodiments.

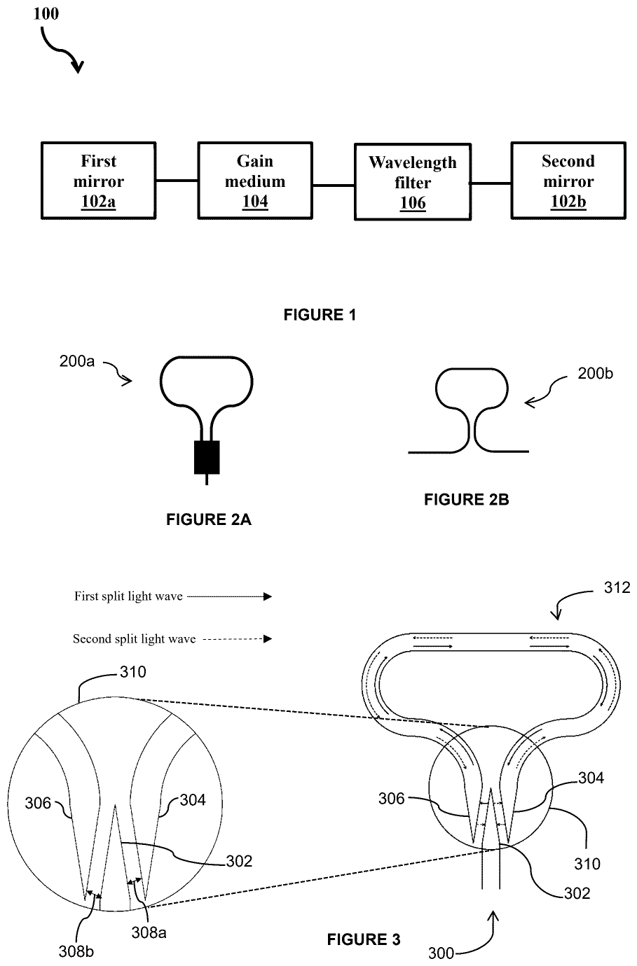

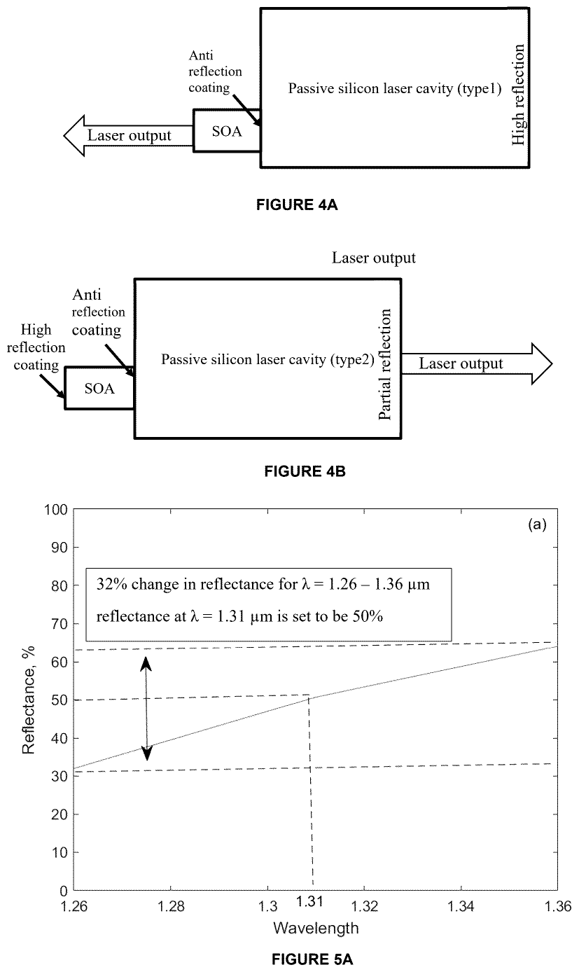

Referring to the FIG. 2A and FIG. 2B, the Sagnac loop and 1×2 MMI-based reflector (200a) which are utilized in conventional hybrid/heterogeneous III-V/Si lasers are based on evanescent and interferometric principles respectively. These two types or reflectors are used in two different types of hybrid III-V/Si lasers as indicated in the FIGS. 4A & 4B. For type 1, the facet of the semiconductor optical amplifier (SOA) that is coupled to the passive silicon laser cavity is anti-reflection (AR) coated. The other facet of the SOA is a cleaved facet that has partial reflectance (i.e., reflectance=30%). The partial reflecting mirror and highly reflecting mirror (i.e., reflectance=100%) for type 1 lasers will be the SOA cleaved facet and a 1×2 MMI-based reflector (200a) respectively. For type 2, the facet of the SOA that is coupled to the passive silicon laser cavity is AR coated. The other facet of the SOA is a high reflection (HR) coated. The partial reflecting mirror and highly reflecting mirror for type 2 lasers will be the Sagnac loop reflector and HR coated facet of the SOA respectively. Therefore, it can be seen that the selection of the reflector type depends on facet of laser emission, if the laser emission should come from the facet of the SOA or silicon photonic chip and hence, type 1 and 2 lasers illustrated in the FIGS. 4A & 4B.

As an example, changes in reflectance of the Sagnac loop reflector (200b) and changes in the insertion loss of the 1×2 MMI reflector across the O-band, are shown in FIGS. 5A & 5B, respectively. The Sagnac loop reflector (200b) is designed with a partial reflectance of 50% at the wavelength of 1310 nm. However, across the O-band of 1260-1360 nm, it can be seen that the reflectance varies from 31% to 63% (as shown in the FIG. 5A). Thereby, the transmission of the Sagnac loop reflector (200b) varies from 69% to 37% across the entire O-band. Such changes in the mirror reflectivity of the laser cavity impacts laser performance (i.e., threshold current, slope efficiency, frequency noise). The 1×2 MMI-based reflector (200a) is optimized at the wavelength of 1310 nm. FIG. 5B indicates the increase in insertion loss away from 1310 nm; from 0.3 dB to 2.3 dB. The increase in the 1×2 MMI-based reflector insertion loss degrades laser performance (i.e., threshold current, slope efficiency).

The reflector (300) as illustrated in the FIG. 3, shows a significant improvement in operation bandwidth and insertion loss levels as compared to the prior art (as shown in the FIG. 2A and FIG. 2B). The reflector (300) comprises a coupling section (310) and a loop section (312) optically coupled to the coupling section (310). The coupling section (310) is formed of multiple waveguides and includes a first port (302) functioning as a power splitter capable of splitting a light wave exiting the first port (302) and a second port (304) and a third port (306) spaced equally from the first port (302). The loop section (312) is formed of a waveguide, preferably bent to form an oval shape. Preferably, the second port (304) and the third port (306) of the coupling section (310) are optically coupled to the loop section (312). More preferably, the second port (304) and the third port (306) of the coupling section (310) form ends of the loop section (312)

A first coupling gap (308a) is formed between the first port (302) and the second port (304), and a second coupling gap (308b) is formed between the first port (302) and the third port (306). The first coupling gap (308a) and the second coupling gap (308b) are symmetrically spaced from each other, so that the coupling section is provided with symmetrically spaced coupling gaps. A light wave exiting the first port (302) is split symmetrically and the split light waves are symmetrically inputted to the second port (304) and the third port (306). Each light wave enters one of the second port (304) and the third port (306), travels along the loop section (312), exits through the other of the second port (302) and the third port (304) and recombines with the other split light wave at the first port (302), as illustrated in the FIG. 3.

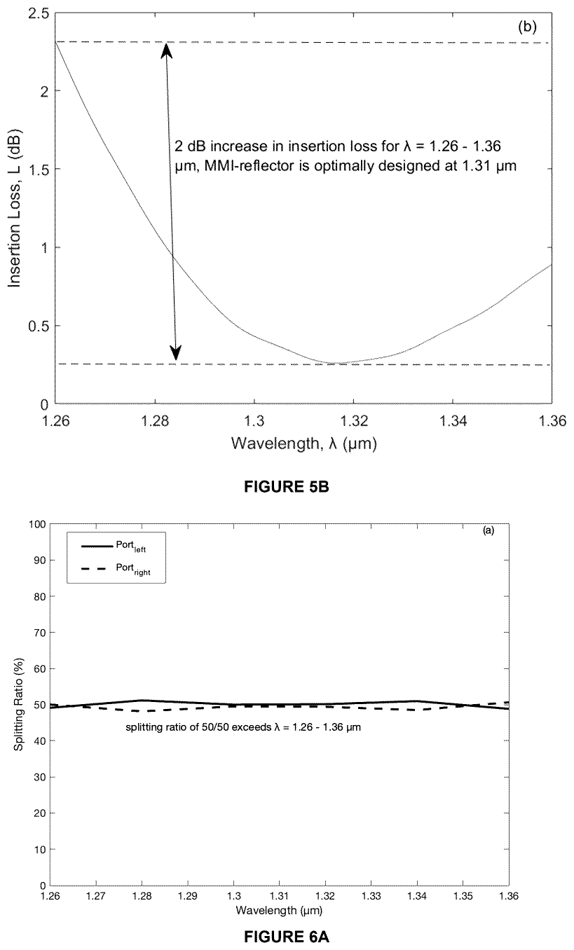

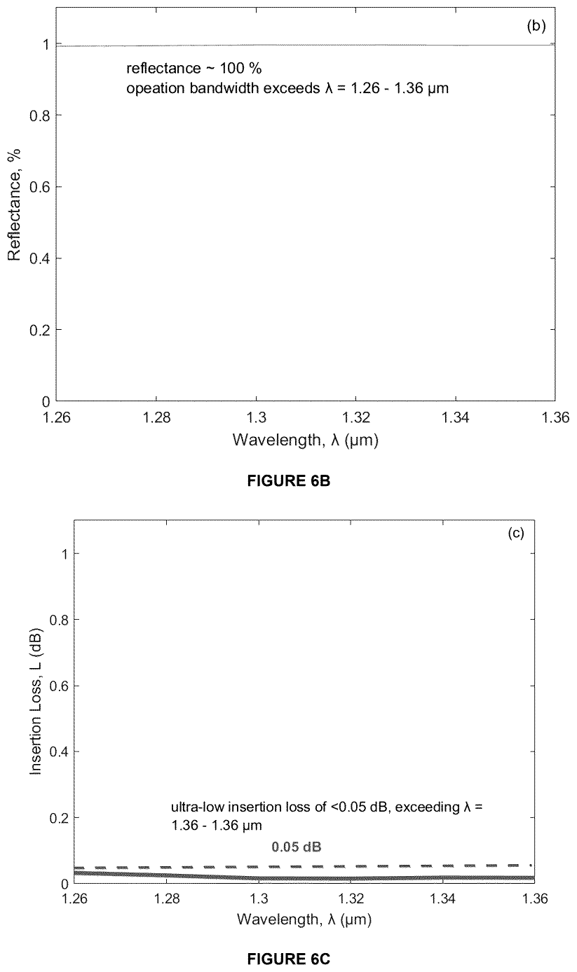

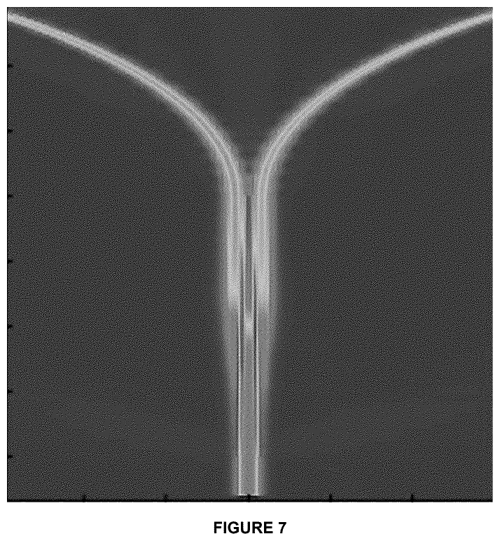

In FIG. 3, the coupling gaps (308a, 308b) are symmetrical where the light wave at the input is split evenly from the first port (302), to a second port (304) and a third port (306). The light waves from the second port (304) and the third port (306) propagates in the loop section (312) in opposite directions and recombines at the coupling section (310), enabling on-chip reflection back to the first port (302). The waveguide radius of the loop section is designed to be greater than 10 microns, such that the no radiation loss due to bending will occur. Thereby, the loop section (312) of the reflector (300) is wavelength independent. FIG. 6A indicates the operation bandwidth of the splitter is larger than the wavelength region of 1260-1360 nm. FIG. 6B and FIG. 6C indicate that the operation bandwidth and insertion loss levels are independent of wavelength at which the reflector (300) is operated. Based on the Finite-difference time-domain (FDTD) simulation results shown in the FIGS. 6A-6C, it can be concluded that broadband operation and low-insertion loss can be observed across 1260-1360 nm; the reflectance is ˜100% in the case for the reflector (300) as illustrated in the FIG. 3. The top-down view of the electric field distribution in the splitter i.e. first port (302) is indicated in the FIG. 7. The reflector (300) as shown in FIG. 3 is capable of functioning as a highly reflecting mirror (i.e., reflectance=100%) and is suitable for type 1 lasers as indicated in the FIG. 4A.

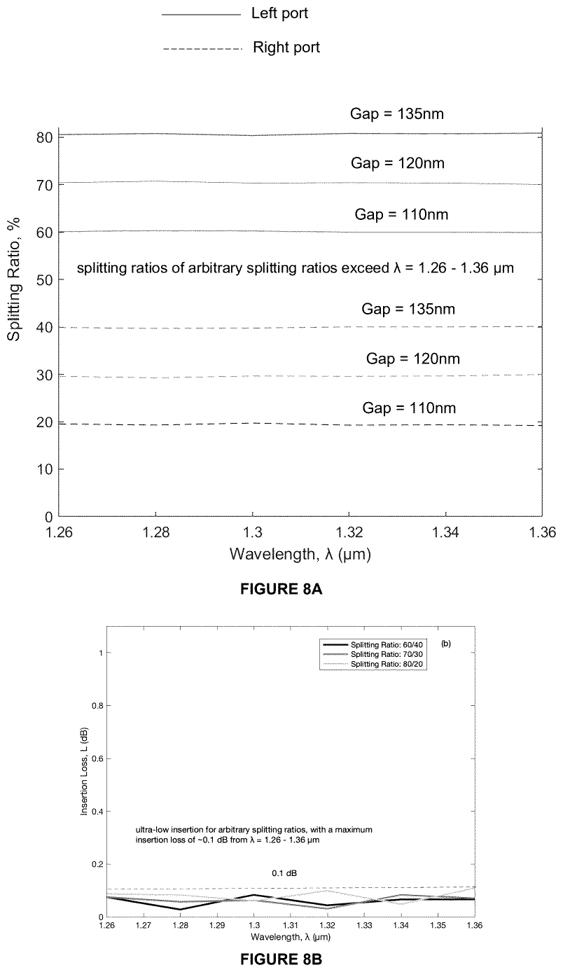

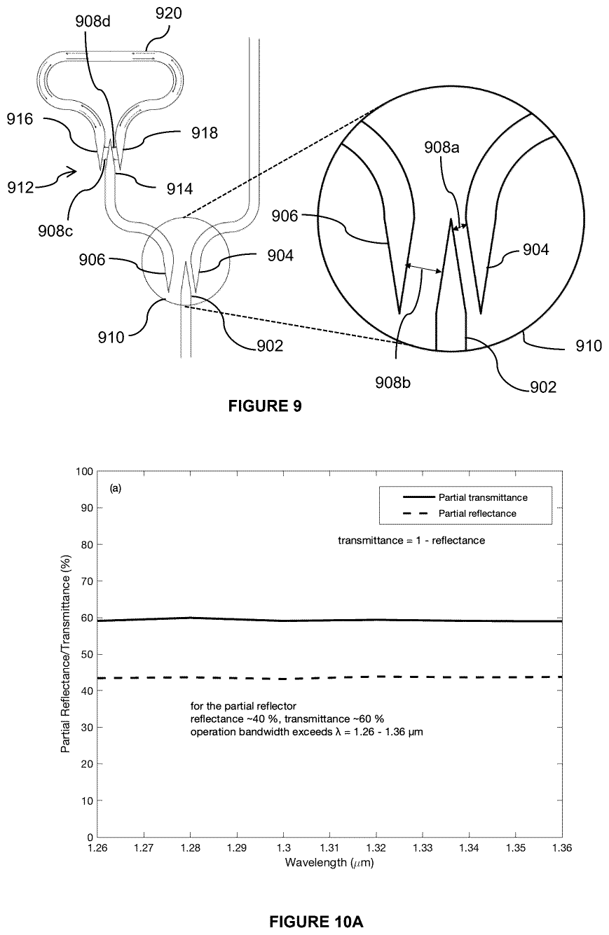

The power splitting ratio of the splitter is adjustable by varying the coupling gaps (308a, 308b), such that one of the coupling gaps (308a, 308b) is narrower than the other coupling gaps (308a, 308b), or in other words the coupling gaps (308a, 308b) are asymmetrically spaced from the first port (302) i.e. splitter. As it can be seen in FIG. 8A and FIG. 8B by fixing the coupling gap on one side to 100 nm, while varying the other side to 150, 200 and 250 nm, power splitting ratios of the 60/40, 70/30 and 80/20 are achieved with broadband operation (as shown in FIG. 8A) with low insertion loss (as FIG. 8B). By exploiting this principle, a partially reflecting reflector (300) with improved broadband operation at low insertion loss can be realized by configuring as in the FIG. 9.

The embodiment of the reflector (900) as in FIG. 9 includes at least two coupling sections (910, 912) and one loop section (920). A first coupling section (910) is formed of multiple waveguides and includes a first port (902), a second port (904) and a third port (906). Similarly, a second coupling section (912) is formed of waveguides and includes a first port (914), a second port (916) and a third port (918), wherein the third port (906) of the first coupling section (910) is optically coupled to the first port (914) of the second coupling section (912), thus forming a cascaded structure. This particular embodiment is applicable to laser architectures that require a partial reflector, for example type 2 laser illustrated in FIG. 4b, wherein the partial reflector is formed as an output port to allow a portion of laser light to be emitted, while the remaining portion of the laser light is reflected back towards the gain section.

The loop section (920) is formed of a waveguide and optically coupled to the second coupling section (912). Preferably, the loop section (920) is optically coupled to the second port (916) and the third port (918) of the second coupling section (912). More preferably, the second port (916) and the third port (918) of the second coupling section (912) form ends of the loop section (920). The loop section (920) is configured as an oval. Each of the coupling sections (910, 912) is configured as a trident, wherein the first port (902, 914) of each of the coupling sections (910, 912) is formed as a center prong of the trident, while the second port (904, 916) and the third port (906, 918) of each of the coupling sections (910, 912) are formed as lateral prongs of the trident.

Each first port (902, 914) includes a first surface adjacent to the corresponding second port (904, 916) and a second surface adjacent to the corresponding third port (906, 918). Similarly, each second port (904, 916) includes a first surface adjacent to the corresponding first port (902, 914) and each third port (906, 918) includes a first surface adjacent to the corresponding first port (902, 914). Preferably, the first surface of each first port (902, 914) is parallel to the first surface of the corresponding second port (904, 916), and the second surface of each first port (902, 914) is parallel to the first surface of the corresponding third port (906, 918).

In the first coupling section (910), the first port (902) and the second port (904) form a first spaced coupling gap (908a) and the first port (902) and the third port (906) form a second spaced coupling gap (908b), wherein the first spaced coupling gap (908a) and the second spaced coupling gap (908b) are asymmetrical;

Similarly, in the second coupling section (912), the first port (914) and the second port (916) form a first spaced coupling gap (908c) and the first port (914) and the third port (918) form a second spaced coupling gap (908d), wherein the first spaced coupling gap (908c) and the second spaced coupling gap (908d) are symmetrical.

Preferably, the first port (914) of the second coupling section (912) is optically coupled to the third port (906) of the first coupling section (912). More preferably, the first port (914) of the second coupling section (912) and the third port (906) of the first coupling section (912) form two ends of a single waveguide.

The coupling gaps (908a, 908b) in the first coupling section (910) are asymmetrical. Thus, the light wave from the first port (902) of the first coupling section (910) is unequally split into two and each split light wave is inputted into one of the second port (904) and the third port (906) of the first coupling section (910). The splitting percentage of light is inversely proportional to the gap width. For example, in FIG. 9, the light wave is split into 60% into the second port (904) and 40% into the third port (906). On the other hand, the coupling gaps (908c, 908d) in the second coupling section (912) are symmetrical. Thus, the light wave from the first port (914) of the second coupling section (912) is equally split into two and each split light wave is inputted into one of the second port (916) and the third port (918) of the second coupling section (913).

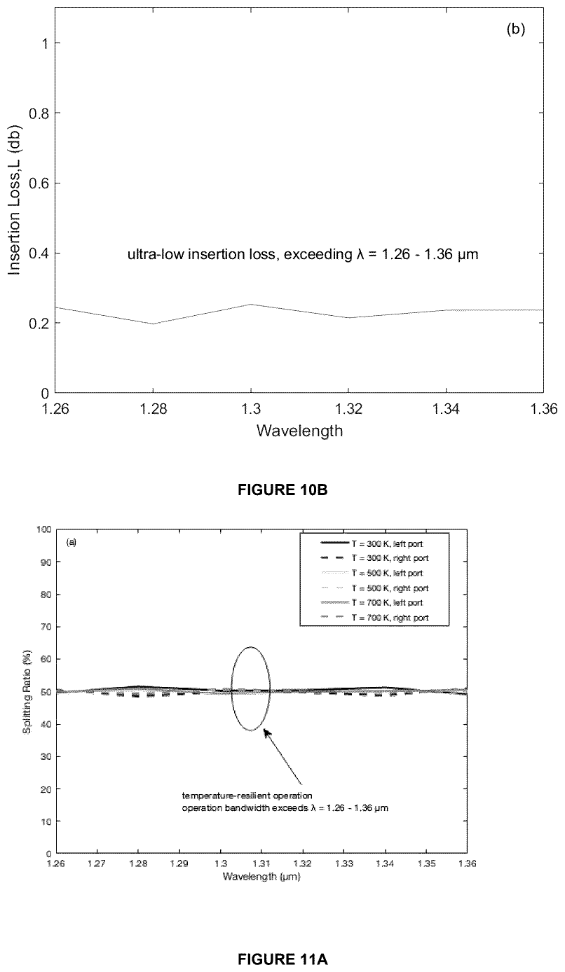

In the first coupling section (910), the light wave through the second port (904) represents transmittance of the reflector (900) (transmittance=1−reflectance). The light wave through the third port (906) the first coupling section (910) propagates to the second coupling section (912), wherein the light wave undergoes full reflectance (reflectance=100%) and returns to the first port (902) of the first coupling section (910), as shown in FIG. 9. FIG. 10A and FIG. 10B show the operation bandwidth and insertion loss respectively of a 60/40 partial reflector implemented according to the architecture illustrated in the FIG. 9. It can be seen from FIG. 8A and FIG. 8B that broadband operation and low insertion loss from 1260-1360 is realized with the present invention. The ports (902, 904, 906, 914, 196, 918) configured as tridents, as in the FIG. 9, split the light waves based on adiabatic mode evolution, and therefore the light splitting operation is free from the influence of wavelength of the light waves and insertion loss is minimized. The reflector (900) of FIG. 9 is mainly applicable for type 2 laser in FIG. 4B.

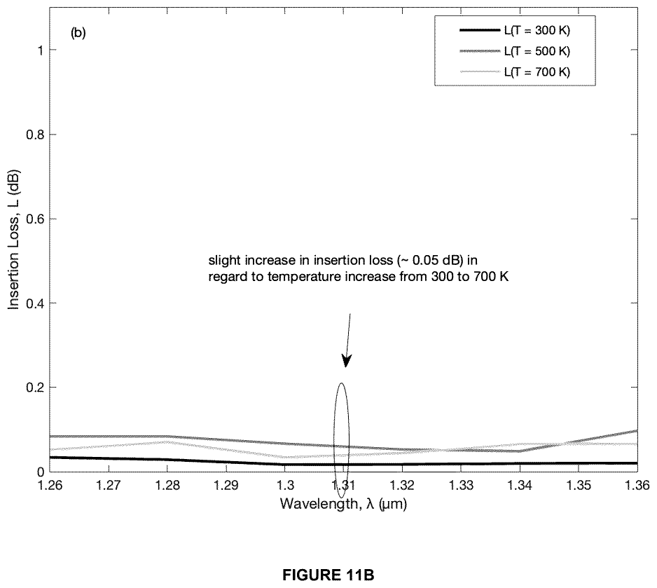

Referring to FIG. 2A and FIG. 2B, the Sagnac loop reflector (200b) and 1×2 MMI-based reflector (200a) are phase dependent. This implies that the operation of the Sagnac loop reflector (200b) and 1×2 MMI-based reflector (200a) is dependent on the effective optical path length that the light wave experiences. As such, when the effective optical path length changes, the device performance will degrade. This issue is significant in platforms such as the silicon-on-insulator (SOI) where the thermo-optic effect of the silicon material is high and fluctuation in environmental temperatures results in changes in effective optical path lengths that the light wave experiences. The reflectors (300 and 900) are based on the adiabatic mode evolution, as such, the reflectors (300 and 900) are not significantly influenced by temperature variations. As shown in FIG. 11A and FIG. 11B, the operation bandwidth and insertion loss levels of a 50/50 splitter respectively clearly indicate that temperature changes do not substantially affect the operation of the reflectors (300, 900) (no shift in curves in FIG. 11A and FIG. 11B in regard to temperature changes).

In a preferred embodiment, the reflector (300) illustrated in FIG. 3 is implemented using silicon on insulator (SOI) platform. Alternatively, the present invention can also be realized using any conventional integrated photonic platform. A fundamental transverse electric (TE)-mode input strip waveguide is tapered at an edge and inserted between two output tapered edges of the same length for forming the trident configuration. With regards to the input TE mode from the first port (302), the light wave will be squeezed out as it travels along the input taper since it will not be supported as the taper width reduces. This principle applies to both symmetrical and asymmetrical splitters in FIGS. 3 & 9.

As the coupling gaps (308a, 308b) of the reflector (300) in the FIG. 3 are symmetrical, the light wave will be split equally and inputted to the second port (304) and the third ports (306). Each split light wave enters one of the second port (304) and the third ports (306), propagates along the loop section (312), exits through the other of the second port (304) and the third ports (306) and then recombines with the other split light wave at the first port (302), thereby, the reflectivity functionality is realized. FIG. 3 illustrates a full reflector (300) where the reflectance is 100%. This reflector (300) will be compatible for the type 1 laser architecture in the FIG. 4A. The coupling section reflector (300) shows wavelength independent operation where its operation bandwidth and insertion loss levels from 1260-1360 nm is shown in the FIG. 6B and FIG. 6C respectively.

The type 2 laser architecture in the FIG. 4B requires a partial laser reflector (i.e., reflectance=60%) as the laser emission results from the silicon photonic chip. In order to realize a partial reflector, two coupling sections (910, 912) can be arranged in a cascaded configuration as shown in the FIG. 9. The first coupling section (910) has asymmetrical coupling gaps (908a, 908b), and hence, light is split asymmetrically (i.e., 60/40) considering the two ports (i.e., second port (904) and third port (906). Following, the light through the second port (904) represents the transmittance of the proposed partial reflector (900) where transmittance=1−reflectance. The light wave through the third port (906) propagates to a full reflector (reflectance=100%) where the coupling gaps (908c, 908d) in the second coupling section (912) are symmetrical and it will split light symmetrically (50/50). The light waves will propagate through the loop section (920) in opposite directions and recombine back at the second coupling section (908) and reflected back to the third port (906) of the first coupling section (910). Following, the light wave will be reflected back from the third port (906) to the first port (902) of the first coupling section (910). As such the reflectance will be reflectance=1−transmittance where the transmittance value is the splitting ratio from the first coupling section (910), to the second port (904). As an overview, for the partial reflector (900) illustrated in FIG. 9, the reflectance and transmittance of the partial reflector (900) is determined by the splitting ratios of the first coupling section (910), which is determined by the spacing of the two coupling gaps (908a, 908b). The second coupling section (912), being symmetrically-spaced, enables the full reflectance (reflectance=100%) of the light wave that is intended to be reflected (as shown in the FIG. 9) to the third port (906) of the first coupling section (910). The operation bandwidth and insertion loss levels of a 60/40 partial splitter is shown in the FIG. 10A and FIG. 10C respectively.

The reflectors (300 and 900) proposed in the present invention operate based on adiabatic mode evolution. In comparison to Sagnac loop reflectors (200b) and 1×2 MMI-based reflectors (200a), the phase dependency on operation can be significantly reduced using he present invention. Thereby, this increases the temperature resiliency of the reflector (300, 900) in contrast to Sagnac loop reflectors (200b) and 1×2 MMI-based reflectors (200a). This is especially pertinent for photonic material platforms such as the SOI, where the thermo-optic coefficient is high and the effective optical path lengths that the light wave experiences can be affected by fluctuations in environmental temperatures.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises”, “comprising”, “including” and “having” are inclusive and therefore specify the presence of stated features, integers, steps, operations, elements and/or components, but do not preclude the presence or addition of one or more other features, integers, steps, operations, elements, components and/or groups thereof. The method steps, processes and operations described herein are not to be construed as necessarily requiring their performance in the particular order discussed or illustrated, unless specifically identified as an order of performance. It is also to be understood that additional or alternative steps may be employed. The use of the expression “at least” or “at least one” suggests the use of one or more elements, as the use may be in one of the embodiments to achieve one or more of the desired objects or results.

1. A reflector (300) for use in a laser architecture, comprises:
i. a coupling section (310) formed of waveguides and including a first port (302), a second port (304) and a third port (306); and
ii. a loop section (312) formed of at least one waveguide and optically coupled to the coupling section (310),
characterized in that the coupling section (310) is configured as a trident, such that a first coupling gap (308a) is formed between the first port (302) and the second port (304) and a second coupling gap (308b) is formed between the first port (302) and the third port (306), wherein the first coupling gap (308a) and the second coupling gap (308a) are symmetric,
wherein the first port (302) is configured to split a light wave exiting the first port (302) and symmetrically input the split light waves into the second port (304) and the third port (306), such that each split light wave entering through one of the second port (304) and the third port (306) travels along the loop section (312), exits through other of the second port (304) and the third port (306) and recombines with the other split light wave at the first port (302).

2. The reflector (300) as claimed in claim 1, wherein a waveguide radius of the loop section (312) is configured to be greater than 10 μm.

3. The reflector (300) as claimed in claim 1, wherein a first surface of the first port (302) is parallel to a first surface of the second port (304) and a second surface of the first port (3020 is parallel to a first surface of the third port (306).

4. The reflector (300) as claimed in claim 1, wherein the laser architecture is a laser cavity.

5. The reflector (300) as claimed in claim 4, wherein the laser cavity is a part of a hybrid III-V/silicon laser device or a heterogeneous III-V/silicon laser.

6. The reflector (300) as claimed in claim 1, wherein the second port (304) and the third port (306) for ends of the waveguide of the loop section (312).

7. The reflector (300) as claimed in claim 1, wherein a reflectivity of the reflector (300) is determined by the splitting ratio of the coupling section (310), a fraction of power split to the second port (304), and the fraction of power split to the third port (306).

8. The reflector (300) as claimed in claim 1, wherein the reflector (300) is at least one of an ultra-broadband on-chip laser coupling section reflector and an ultra-broadband coupling section laser reflector.

9. The reflector (300) as claimed in claim 1, wherein the reflector (300) is operable in at least one of an O band, C band and L band.

10. A reflector (900) for use in a laser architecture, comprising:
i. a first coupling section (910) formed of waveguides and including a first port (902), a second port (904) and a third port (906);
ii. a second coupling section (912) formed of waveguides and including a first port (914), a second port (916) and a third port (918);
iii. a loop section (920) formed of a waveguide and optically coupled to the second coupling section (912),
characterized in that:
in the first coupling section (910), the first port (902) and the second port (904) form a first spaced coupling gap (908a) and the first port (902) and the third port (906) form a second spaced coupling gap (908b), wherein the first spaced coupling gap (908a) and the second spaced coupling gap (908b) are asymmetrical;
in the second coupling section (912), the first port (914) and the second port (916) form a first spaced coupling gap (908c) and the first port (914) and the third port (918) form a second spaced coupling gap (908d), wherein the first spaced coupling gap (908c) and the second spaced coupling gap (908d) are symmetrical, wherein the first port (914) of the second coupling section (912) is optically coupled to the third port (906) of the first coupling section (912).
